(19) United States
(12) Patent Application Publication
(10) Pub. No.: US 2026/0309753 A1
(43) Pub. Date: Oct. 8, 2026

(54) CURRENT SENSOR AND MANUFACTURING METHOD OF CURRENT SENSOR

(71) Applicant: Asahi Kasei Microdevices Corporation, Tokyo (JP)

(72) Inventors: Masaki Tsujimoto, Tokyo (JP); Yasutaka Myoraku, Tokyo (JP); Keita Yamaguchi, Tokyo (JP)

(73) Assignee: Asahi Kasei Microdevices Corporation, Tokyo (JP)

(21) Appl. No.: 19/554,648

(22) Filed: Mar. 3, 2026

(30) Foreign Application Priority Data
Apr. 4, 2025 (JP) 2025-062794
Dec. 22, 2025 (JP) 2025-273926

(51) Int. Cl. G01R 15/20; G01R 3/00; G01R 19/00; H10W 70/04; H10W 74/01

(52) U.S. Cl. CPC G01R 15/207; G01R 3/00; G01R 15/202; G01R 19/0092; H10W 70/048; H10W 74/016

(57) ABSTRACT

Current sensor includes integrally configured sealing part sealing magnetoelectric conversion element, part of current conductor, electrical conductor, signal processing IC, part of signal conductor. In current conductor, first terminal surface is exposed from first surface of sealing part facing first surface of support part, second terminal surface exposed from second surface continuous from first surface of sealing part. In signal conductor, third terminal surface is exposed from first surface of sealing part, fourth terminal surface exposed from third surface opposite second surface of sealing part. At least two surfaces among first surface, second surface, side surface of support part contact sealing part without being exposed from sealing part. First surface of sealing part, first terminal surface, third terminal surface are on same plane. Second surface of sealing part and second terminal surface are on same plane. Third surface of sealing part and fourth terminal surface are on same plane.

### CROSS-REFERENCE TO RELATED APPLICATION

This application claims the priority benefits of Japanese application no. 2025-062794, filed on Apr. 4, 2025 and Japanese application no. 2025-273926, filed on Dec. 22, 2025. The entirety of the above-mentioned patent application is hereby incorporated by reference herein and made a part of this specification.

### BACKGROUND

### TECHNICAL FIELD

The disclosure relates to a current sensor and a manufacturing method of current sensor.

### Related Art

Patent Document 1 describes manufacturing a current sensor by covering an upper surface side with a first sealing member and covering a bottom surface side with a second sealing member. Patent Document 2 describes a current sensor including a plate-shaped support part that supports a magnetoelectric conversion element and a signal processing IC on a surface on a ceiling surface side of a sealing part and is separated from a conductor.

### Citation List

### Patent Document

Patent Document 1 Japanese Patent No. 6971908

Patent Document 2 Japanese Patent No. 7329118

A current sensor is desired that is capable of ensuring surface distance, prevent cracks and the like from occurring within the sealing part, ensure withstand voltage, and enable miniaturization.

### SUMMARY

A current sensor according to one aspect of the disclosure may include at least one magnetoelectric conversion element. The current sensor may include a current conductor that at least partially surrounds the at least one magnetoelectric conversion element in plan view and through which a measurement current measured by the at least one magnetoelectric conversion element flows. The current sensor may include a signal processing IC that processes a signal output from the at least one magnetoelectric conversion element. The current sensor may include a support part that supports, with a first surface, at least one of a surface opposite to a magnetic sensing surface of the at least one magnetoelectric conversion element and a surface opposite to a circuit surface of the signal processing IC. The current sensor may include a signal conductor that is connected to the circuit surface of the signal processing IC via electrical conductor and transmits a signal output from the signal processing IC. The current sensor may include a sealing part integrally configured that seals the at least one magnetoelectric conversion element, a part of the current conductor, the electrical conductor, the signal processing IC, a part of the signal conductor, and at least a part of the support part. In a case where a surface of the support part opposite to the first surface is defined as a second surface, at least two surfaces among the first surface, the second surface, and a side surface of the support part may be in contact with the sealing part without being exposed from the sealing part. The current conductor may have a first terminal surface exposed from a first surface of the sealing part facing the first surface of the support part, and a second terminal surface exposed from a second surface continuous from the first surface of the sealing part. The signal conductor may have a third terminal surface exposed from the first surface of the sealing part, and a fourth terminal surface exposed from a third surface opposite to the second surface of the sealing part. The second surface of the sealing part and the second terminal surface may be located on an approximately same plane. The third surface of the sealing part and the fourth terminal surface may be located on an approximately same plane.

A manufacturing method of current sensor according to one aspect of the disclosure may include: preparing a lead frame in which a plurality of sets of a current conductor through which a measurement current measured by at least one magnetoelectric conversion element flows and a signal conductor that transmits a signal output from a signal processing IC that processes a signal output from the at least one magnetoelectric conversion element are formed, in which a first surface of a support part is partially adhered to a second surface of the lead frame. The manufacturing method may include: arranging the at least one magnetoelectric conversion element on the first surface of the support part so as to be at least partially surrounded by the current conductor in plan view, and arranging the signal processing IC at a position different from a position where the at least one magnetoelectric conversion element is arranged on the first surface of the support part. The manufacturing method may include: electrically connecting the at least one magnetoelectric conversion element and the signal processing IC by electrical conductor, and electrically connecting the signal processing IC and the signal conductor by electrical conductor. The manufacturing method may include: pasting a film on a first surface opposite to the second surface of the lead frame. The manufacturing method may include: arranging the lead frame in a cavity of a mold with a gap formed between the cavity and the support part. The manufacturing method may include: filling mold resin into the cavity and sealing the at least one magnetoelectric conversion element, the signal processing IC, the support part, and the electrical conductor with the mold resin. The manufacturing method may include: removing the film from the first surface of the lead frame sealed with the mold resin. The manufacturing method may include: singulating the lead frame sealed with the mold resin by cutting.

### BRIEF DESCRIPTION OF THE DRAWINGS

FIG. 1 is an enlarged view of a part of the sealing part when a mold sealing process is performed twice.

FIG. 2A is a schematic plan view of the current sensor according to the first embodiment as viewed from the mounting surface side (z-axis direction).

FIG. 2B is a cross-sectional view of the current sensor shown in FIG. 2A taken along line A-A.

FIG. 3 An enlarged view of an electrical connection portion between the magnetoelectric conversion element and the signal processing IC.

FIG. 4A is a schematic plan view of the current sensor according to the second embodiment as viewed from the mounting surface side (z-axis direction).

FIG. 4B is a cross-sectional view of the current sensor shown in FIG. 4A taken along line A-A.

FIG. 5A is a schematic plan view of the current sensor according to the third embodiment as viewed from the mounting surface side (z-axis direction).

FIG. 5B is a cross-sectional view of the current sensor shown in FIG. 5A taken along line A-A.

FIG. 6A is a schematic plan view of the current sensor according to the fourth embodiment as viewed from the mounting surface side (z-axis direction).

FIG. 6B is a cross-sectional view of the current sensor shown in FIG. 6A taken along line A-A.

FIG. 7A is a schematic plan view of the current sensor according to the fifth embodiment as viewed from the mounting surface side (z-axis direction).

FIG. 7B is a cross-sectional view of the current sensor shown in FIG. 7A taken along line A-A.

FIG. 8A is a schematic plan view of the current sensor according to the sixth embodiment as viewed from the mounting surface side (z-axis direction).

FIG. 8B is a cross-sectional view of the current sensor shown in FIG. 8A taken along line A-A.

FIG. 9A is a schematic plan view of the current sensor according to the seventh embodiment as viewed from the mounting surface side (z-axis direction).

FIG. 9B is a cross-sectional view of the current sensor shown in FIG. 9A taken along line A-A.

FIG. 10 is a schematic diagram showing a case where two magnetoelectric conversion elements are arranged in the seventh embodiment.

FIG. 11A is a diagram for describing a manufacturing method of the current sensor.

FIG. 11B is a diagram for describing a manufacturing method of the current sensor.

FIG. 12A is a plan view showing a state after finishing Process 2 for realizing the first embodiment.

FIG. 12B is a plan view showing a state after finishing Process 2 for realizing the seventh embodiment.

FIG. 13 is a cross-sectional view showing an example of a state where the current sensor is mounted on a substrate.

### DESCRIPTION OF THE EMBODIMENTS

A current sensor according to one aspect of the disclosure may include at least one magnetoelectric conversion element. The current sensor may include a current conductor that at least partially surrounds the at least one magnetoelectric conversion element in plan view and through which a measurement current measured by the at least one magnetoelectric conversion element flows. The current sensor may include a signal processing IC that processes a signal output from the at least one magnetoelectric conversion element. The current sensor may include a support part that supports, with a first surface, at least one of a surface opposite to a magnetic sensing surface of the at least one magnetoelectric conversion element and a surface opposite to a circuit surface of the signal processing IC. The current sensor may include a signal conductor that is connected to the circuit surface of the signal processing IC via electrical conductor and transmits a signal output from the signal processing IC. The current sensor may include a sealing part integrally configured that seals the at least one magnetoelectric conversion element, a part of the current conductor, the electrical conductor, the signal processing IC, a part of the signal conductor, and at least a part of the support part. In a case where a surface of the support part opposite to the first surface is defined as a second surface, at least two surfaces among the first surface, the second surface, and a side surface of the support part may be in contact with the sealing part without being exposed from the sealing part. The current conductor may have a first terminal surface exposed from a first surface of the sealing part facing the first surface of the support part, and a second terminal surface exposed from a second surface continuous from the first surface of the sealing part. The signal conductor may have a third terminal surface exposed from the first surface of the sealing part, and a fourth terminal surface exposed from a third surface opposite to the second surface of the sealing part. The second surface of the sealing part and the second terminal surface may be located on an approximately same plane. The third surface of the sealing part and the fourth terminal surface may be located on an approximately same plane.

In the current sensor, the first surface of the sealing part, the first terminal surface, and the third terminal surface may be located on an approximately same plane.

In any of the current sensors, the sealing part may include an inorganic filler.

In any of the current sensors, the sealing part may have no interface within the sealing part that does not substantially cross the filler.

In any of the current sensors, the signal conductor may be in contact with the first surface of the support part.

In any of the current sensors, a cross section of the filler may exist on a surface of the sealing part.

In any of the current sensors, the sealing part may have a fourth surface opposite to the first surface, a fifth surface, and a sixth surface opposite to the fifth surface. The interface within the sealing part that does not substantially cross the filler may not need to be exposed on the fifth surface and the sixth surface.

In any of the current sensors, the sealing part may have a fourth surface opposite to the first surface, a fifth surface, and a sixth surface opposite to the fifth surface. A cross section of the filler on the fifth surface and the sixth surface of the sealing part may be exposed at a same ratio within a range of 5% as a filling rate of the filler in the sealing part.

In any of the current sensors, in a case where a minimum distance along the first surface of the sealing part between the first terminal surface and the third terminal surface is defined as a surface distance, the surface distance is 79% or more of a length of the sealing part in a direction along the surface distance.

In any of the current sensors, in a case where a minimum distance along the first surface of the sealing part between the first terminal surface and the third terminal surface is defined as a surface distance, the surface distance may be 85% or more of a length of the sealing part in a direction along the surface distance.

In any of the current sensors, in a case where a minimum distance along the first surface of the sealing part between the first terminal surface and the third terminal surface is defined as a surface distance, the surface distance may be 8 mm or less.

In any of the current sensors, among members sealed in the sealing part, members exposed from a surface of the sealing part may be only the first terminal surface and the second terminal surface of the current conductor, and the third terminal surface and the fourth terminal surface of the signal conductor.

In any of the current sensors, at least a part of a second surface opposite to a first surface of the current conductor on a same side as the first surface of the sealing part, and the first surface of the support part may be located on a same plane.

In any of the current sensors, the current conductor may have a step part such that a second surface opposite to a first surface facing the first surface of the sealing part is separated from the first surface of the support part.

In any of the current sensors, the sealing part may seal the support part, and the support part may not need to be exposed from the sealing part.

In any of the current sensors, the sealing part may seal a part of the support part, the support part may be insulating, and an end part of the support part may be exposed from the sealing part.

In any of the current sensors, the sealing part may have a fourth surface opposite to the first surface, a fifth surface, and a sixth surface opposite to the fifth surface. An exposed surface of the end part exposed from the sealing part may be located on a same plane as the fifth surface or the sixth surface of the sealing part.

In any of the current sensors, the support part may be separated from both the current conductor and the signal conductor, and a part of the sealing part may exist between the current conductor and the signal conductor.

In any of the current sensors, the magnetoelectric conversion element and the signal processing IC may be connected by a wire, and a roundness having a radius of 20% or more of a plate thickness of the current conductor may exist in the current conductor at a position facing the wire.

In any of the current sensors, the sealing part may have a fourth surface opposite to the first surface. A plane in which a ratio of an area of a filler to an area of the sealing part is half or less of an average filling rate of the filler in mold resin constituting the sealing part may exist only on the first surface and the fourth surface, among planes existing inside or on a surface of the sealing part.

In any of the current sensors, the magnetic sensing surface of the magnetoelectric conversion element and the circuit surface of the signal processing IC may be arranged facing the first terminal surface and the second terminal surface side, and a distance between the magnetic sensing surface and the first surface of the sealing part may be smaller than a thickness of a lead frame.

In any of the current sensors, there may be further included a substrate on which the current sensor is mounted via solder, and a metal plate may be arranged in the substrate at a position facing the magnetoelectric conversion element.

In any of the current sensors, the sealing part may have a fourth surface opposite to the first surface, a fifth surface of the sealing part sharing sides with both the first surface and the fourth surface, and a sixth surface opposite to the fifth surface. Among the first surface, the fourth surface, the fifth surface, and the sixth surface of the sealing part, only an insulator may exist at a location sandwiched between the first terminal surface and the third terminal surface in top view.

In any of the current sensors, the current conductor may have a step in a direction away from the support part in side view, the support part may exist only between the step and the third terminal surface in plan view, and an end surface of the support part may overlap with an end part of the signal conductor.

In any of the current sensors, the support part may be separated from the signal conductor in top view.

A manufacturing method of current sensor according to one aspect of the disclosure may include: preparing a lead frame in which a plurality of sets of a current conductor through which a measurement current measured by at least one magnetoelectric conversion element flows and a signal conductor that transmits a signal output from a signal processing IC that processes a signal output from the at least one magnetoelectric conversion element are formed, in which a first surface of a support part is partially adhered to a second surface of the lead frame. The manufacturing method may include: arranging the at least one magnetoelectric conversion element on the first surface of the support part so as to be at least partially surrounded by the current conductor in plan view, and arranging the signal processing IC at a position different from a position where the at least one magnetoelectric conversion element is arranged on the first surface of the support part. The manufacturing method may include: electrically connecting the at least one magnetoelectric conversion element and the signal processing IC by electrical conductor, and electrically connecting the signal processing IC and the signal conductor by electrical conductor. The manufacturing method may include: pasting a film on a first surface opposite to the second surface of the lead frame. The manufacturing method may include: arranging the lead frame in a cavity of a mold with a gap formed between the cavity and the support part. The manufacturing method may include: filling mold resin into the cavity and sealing the at least one magnetoelectric conversion element, the signal processing IC, the support part, and the electrical conductor with the mold resin. The manufacturing method may include: removing the film from the first surface of the lead frame sealed with the mold resin. The manufacturing method may include: singulating the lead frame sealed with the mold resin by cutting.

In the manufacturing method, the cavity of the mold may be flat over regions of a plurality of current sensors.

In any of the manufacturing methods, the lead frame may be formed by etching.

In any of the manufacturing methods, there may be included: removing organic matter from a surface where the lead frame is exposed, after removing the film.

Note that the above summary of the disclosure does not enumerate all of the features of the disclosure. Sub-combinations of these feature groups may also constitute disclosures.

Hereinafter, the disclosure is described through embodiments of the disclosure, but the following embodiments do not limit the disclosure according to the claims. Not all combinations of features described in the embodiments are necessarily essential to the solution means of the disclosure.

The current sensor includes a current conductor through which a measurement current of a measurement target flows, a magnetoelectric conversion element that detects a magnetic field generated due to the measurement current, and a signal processing IC that amplifies a signal of the magnetoelectric conversion element and outputs the signal to the outside, and is provided as one semiconductor package by sealing the current conductor, the magnetoelectric conversion element, and the signal processing IC with resin.

For example, Patent Document 1 discloses a manufacturing method of current detection device including: arranging a conductor through which a measured current flows and a magnetic sensor that detects a magnetic field generated by the current flowing through the conductor on a support member so as to be spaced apart from each other; sealing at least a part of the conductor and an upper surface of the magnetic sensor with a first sealing member; removing the support member; and sealing at least a part of the conductor and a bottom surface of the magnetic sensor with a second sealing member.

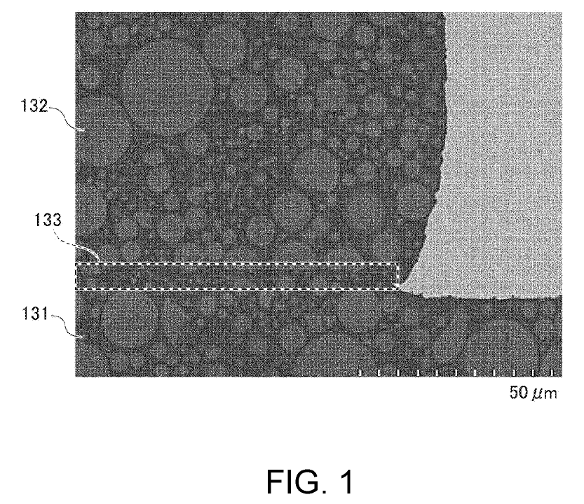

As in the manufacturing method described in Patent Document 1, when the sealing part is configured by the first sealing member and the second sealing member, it is necessary to perform the mold sealing process twice. Moreover, by performing the mold sealing process twice, as shown in FIG. 1, an interface 133 is formed between a mold resin layer 132 formed in the first mold sealing process and a mold resin layer 131 formed in the second mold sealing process. When the interface 133 exists, there is a possibility that peeling or cracking may occur at the interface 133.

Moreover, as in Patent Document 2, when terminals protrude from a side surface of the sealing part, the entire current sensor becomes large in size.

In consideration of the above, the current sensor according to each embodiment provides a current sensor with high withstand voltage performance that can ensure a surface distance even when made compact and can suppress occurrence of peeling or cracking within the sealing part.

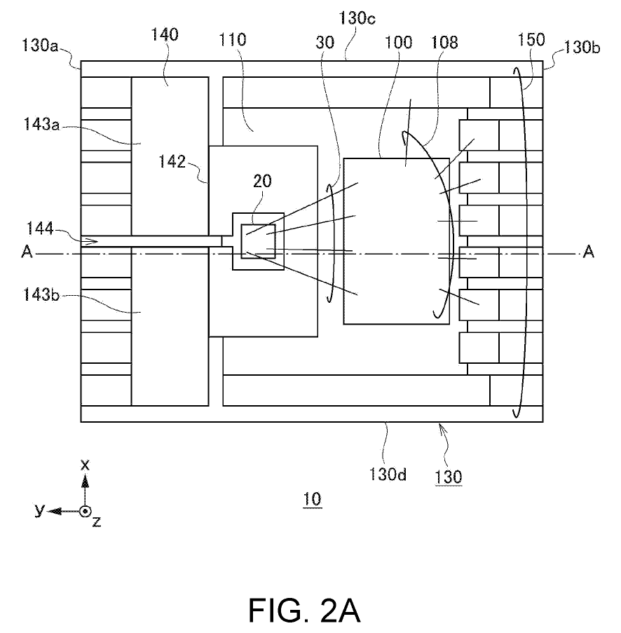

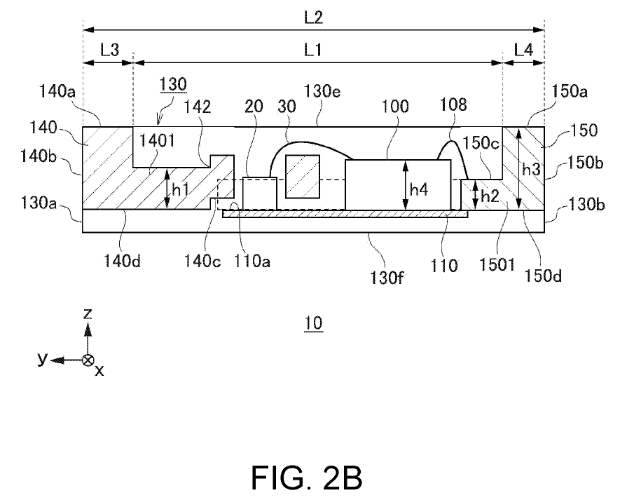

FIG. 2A and FIG. 2B show an internal configuration of a current sensor 10 according to a first embodiment. FIG. 2A is a schematic plan view of the current sensor 10 according to the first embodiment as viewed from a mounting surface side (z-axis direction). FIG. 2B is a cross-sectional view of the current sensor 10 shown in FIG. 2A taken along line A-A.

The current sensor 10 includes a signal processing IC 100, a magnetoelectric conversion element 20, a support part 110, a sealing part 130, a current conductor 140, and a signal conductor 150. The magnetoelectric conversion element 20 is electrically connected to the signal processing IC 100 via a wire 30. The signal processing IC 100 is electrically connected to the signal conductor 150 via a wire 108.

The sealing part 130 seals the magnetoelectric conversion element 20, the signal processing IC 100, the support part 110, a part of the current conductor 140, a part of the signal conductor 150, the wire 30, and the wire 108 with resin. The resin may be, for example, an epoxy-based thermosetting resin to which silica is added. The pair of current conductors 140 are primary-side lead terminals. The signal conductor 150 is a plurality of secondary-side lead terminals.

Coordinates are defined as follows: in FIG. 2A, the x-axis direction is parallel to the paper surface and oriented from bottom to top, the y-axis direction is parallel to the paper surface and oriented from right to left, and the z-axis direction is perpendicular to the paper surface and oriented from back to front. Any one axis among the x-axis, the y-axis, and the z-axis is orthogonal to the other axes.

The magnetoelectric conversion element 20 detects a magnetic field in a specific direction that changes according to a measurement current flowing through the current conductor 140, and the signal processing IC 100 amplifies a signal corresponding to the magnitude of the magnetic field and outputs the amplified signal via the signal conductor 150. The magnetoelectric conversion element 20 is made of a compound semiconductor formed on a GaAs substrate and may be a chip cut out in a square or rectangular shape in a plan view from the z-axis direction. The magnetoelectric conversion element 20 may be a vertical magnetic field detection element, for example, a Hall element utilizing the Hall effect having a sensitivity axis in a direction intersecting a magnetic sensing surface. The magnetoelectric conversion element 20 may also be a horizontal magnetic field detection element, for example, a magnetoresistive element or a fluxgate element that detects a magnetic field in any one axis direction on a xy plane along the magnetic sensing surface. The magnetoresistive element may be, for example, a semiconductor magnetoresistive element (SMR), an anisotropic magnetoresistive element (AMR), a giant magnetoresistive element (GMR), or a tunnel magnetoresistive element (TMR).

In the first embodiment, an example in which the current sensor 10 includes one magnetoelectric conversion element 20 is described. However, the current sensor 10 may include two or more magnetoelectric conversion elements 20.

The current conductor 140 has a U-shape in a plan view and has a slit 144 extending in the y-axis direction in a central portion. The magnetoelectric conversion element 20 is disposed within the slit 144. The current conductor 140 at least partially surrounds side surfaces of the magnetoelectric conversion element 20, and a measurement current measured by the magnetoelectric conversion element 20 flows therethrough. The current conductor 140 may surround at least three side surfaces of the magnetoelectric conversion element 20.

The signal processing IC 100 is a large-scale integrated circuit (LSI). The signal processing IC 100 is electrically connected to the magnetoelectric conversion element 20 via the wire 30. The signal processing IC 100 is cut out in a rectangular or square shape in a plan view. Furthermore, the signal processing IC 100 is electrically connected to at least two lead terminals among a plurality of lead terminals constituting the signal conductor 150 via the wire 108. The wire 30 and the wire 108 may be formed of a conductor material having Au, Ag, Cu, or Al as a main component. The wire 30 is an example of electrical conductor. The electrical conductor may be a clip.

The signal processing IC 100 is a signal processing circuit composed of a Si monolithic semiconductor formed on a Si substrate. A compound semiconductor substrate may be used instead of the Si substrate. The signal processing circuit processes an output signal corresponding to a magnitude of a magnetic field output from the magnetoelectric conversion element 20. The signal processing circuit outputs an output signal indicating a current value of a measurement current flowing through the current conductor 140 via the signal conductor 150 based on the output signal. The signal processing circuit of the signal processing IC 100 includes at least a circuit that inputs a minute output signal corresponding to a magnitude of a magnetic field of the magnetoelectric conversion element and amplifies the input signal. The signal processing circuit of the signal processing IC 100 may include a circuit that corrects characteristics of the magnetoelectric conversion element 20 according to temperature or stress.

The current conductor 140 constitutes a pair of lead terminals 143a, 143b. A measurement current is input from one lead terminal 143a of the pair of lead terminals 143a, 143b, and the measurement current is output from the other lead terminal 143b. Each of the pair of lead terminals 143a, 143b may have a tip portion divided into a plurality of portions. That is, on the surface of the current sensor 10, exposed surfaces of the pair of lead terminals 143a, 143b may each be divided into a plurality of terminal surfaces.

The measurement current flowing through the current conductor 140 flows from one end of the U-shape to the other end along the U-shape. As a result, a magnetic field corresponding to the magnitude of the measurement current and the distance from the current conductor 140 is generated around the current conductor 140. At the position where the magnetoelectric conversion element 20 is disposed, a magnetic field is generated such that the z-axis direction component becomes largest. Since the magnetoelectric conversion element 20 is disposed in the slit 144, high sensitivity to the measurement current is obtained.

The signal conductor 150 has a plurality of lead terminals that transmit signals output from the signal processing IC 100. The signal conductor 150 may be constituted by a lead frame of a conductive material having copper as a main component together with the current conductor 140.

The support part 110 is a sheet-shaped member, supports the magnetoelectric conversion element 20 and the signal processing IC 100 on a surface 110a on the mounting surface side of the sealing part 130, and is separated from the current conductor 140. The support part 110 may be composed of multiple pieces. At least a part of the surface 140dopposite to a terminal surface 140a of the current conductor 140 on the same side as a surface 130e of the sealing part 130, and the surface 110a of the support part 110 are located on the same plane. However, the current conductor 140 has a step part 142 in a direction separated from the support part 110 so as not to contact the support part 110. That is, the current conductor 140 has the step part 142 such that the surface 110a of the support part 110 and the surface 140c of the current conductor 140 facing the surface 110a are separated in the thickness direction of the current conductor 140. Therefore, the support part 110 and the step part 142 do not overlap, and the support part 110 exists on the signal conductor 150 side. The step part 142 may be provided on the current conductor 140 by half etching or half-cut processing so that the support part 110 and the current conductor 140 do not contact. In the case where the step part 142 is formed by half etching, there is no need to prepare a special mold when forming the lead frame, and efficient manufacturing is possible. In the case where the step part 142 is formed by half-cut processing, the thickness of the current conductor 140 can be maintained, and heat generation when a current to be measured flows can be suppressed. In this case, the step part 142 exists at a position that does not overlap with the terminal surface 140a when viewed from the z-axis direction, that is, at a portion where the thickness of the lead frame is thin, so that a sufficient area of the terminal surface can be secured, and mounting of the current sensor 10 on a substrate becomes easy. By providing the step part 142, it becomes easier to maintain withstand voltage performance in the case where peeling occurs between the mold resin and the support part 110, compared to the case where the support part 110 and the current conductor 140 are in contact. Since the support part 110 is held by the signal conductor 150, an end surface of the support part 110 and an end surface of the signal conductor 150 may overlap in plan view.

The current conductor 140 and the signal conductor 150 may be formed by half etching the lead frame. In the case of being constituted by half etching, the edge part of the etched portion is rounded. The radius of the roundness depends on the plate thickness of the lead frame, and is 20% or more of a thickness h1of the portion where the thickness of the current conductor 140 is thinner than other portions, that is, the thickness h1 of a portion 1401 sealed within the sealing part 130.

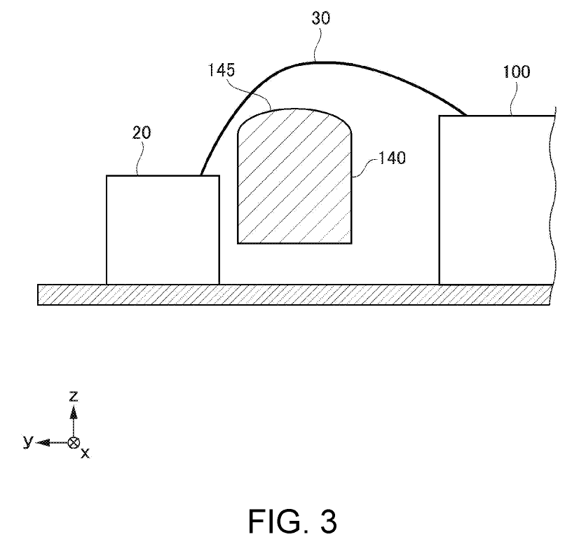

FIG. 3 is an enlarged view of the electrical connection portion between the magnetoelectric conversion element 20 and the signal processing IC 100. In the case where the current conductor 140 is formed by half etching, an edge part 145 is rounded. When the edge part 145 is rounded, the wire 30 connecting the magnetoelectric conversion element 20 and the signal processing IC 100 becomes difficult to contact the current conductor 140. In other words, the withstand voltage can be improved between the current conductor 140 and the magnetoelectric conversion element 20 or the signal processing IC 100, or a signal processing system including the magnetoelectric conversion element 20 and the signal processing IC 100.

The support part 110 contacts, on the surface 110a on the same side as the surface 130e that is the mounting surface of the sealing part 130, a surface 150d of the signal conductor 150 opposite to the surface 150c facing the surface 130e of the sealing part 130. The signal conductor 150 may be adhered to the surface 110a of the support part 110 via an adhesive layer, similarly to the magnetoelectric conversion element 20 and the signal processing IC 100. The support part 110 may be constituted by an insulating member having a low elastic modulus, such as a polymer tape such as polyimide tape. The support part 110 may be constituted by a member such as silicon, which is connected to the lead frame constituting the current conductor 140 and the signal conductor 150 via an adhesive, and has a linear expansion coefficient close to the linear expansion coefficient of the signal processing IC or the magnetoelectric conversion element 20. The support part 110 may be constituted by a member having a thickness of less than 0.1 mm. This can reduce the stress acting on the signal processing IC due to changes in heat generated within the sealing part 130.

The current sensor 10 is a SON type semiconductor package, similarly to the current sensor shown in Patent Document 1. More specifically, in the current conductor 140, the terminal surface 140a is exposed from the surface 130e that is the mounting surface of the sealing part 130 facing the surface 110a of the support part 110, and a terminal surface 140b is exposed from a surface 130a that is a side surface continuous from the surface 130e of the sealing part 130. The terminal surface 140a and the terminal surface 140b are connected. The terminal surface 140b is a surface extending from the terminal surface 140a along the surface 130e that is the mounting surface of the sealing part 130 toward the surface 130f of the sealing part 130, and the terminal surface 140a and the terminal surface 140b are continuous surfaces.

In the signal conductor 150, a terminal surface 150a is exposed from the surface 130e of the sealing part 130, and a terminal surface 150b is exposed from a surface 130b that is a side surface opposite to the surface 130a of the sealing part 130. The terminal surface 150b is a surface extending from the terminal surface 150a along the surface 130e that is the mounting surface of the sealing part 130 toward the surface 130f of the sealing part 130, and the terminal surface 150a and the terminal surface 150b are continuous surfaces.

The surface 130e of the sealing part 130, the terminal surface 140a of the current conductor 140, and the terminal surface 150a of the signal conductor 150 are located on approximately the same plane or the same plane. The terminal surfaces 140a, 150a may protrude with a thickness within 50 μm or within 20 μm from the surface 130e of the sealing part 130, such as by being provided with exterior plating constituted by a non-magnetic material including Sn or the like. In this specification, when the difference in height in the z-axis direction between the terminal surface 140a of the current conductor 140 and the terminal surface 150a of the signal conductor 150 and the surface 130e of the sealing part 130 is within 50 μm, the surface 130e of the sealing part 130, the terminal surface 140a of the current conductor 140, and the terminal surface 150a of the signal conductor 150 may be regarded as being located on approximately the same plane. The difference in height is preferably within 20 μm.

The surface 130a of the sealing part 130 and the terminal surface 140b of the current conductor 140 are located on approximately the same plane or the same plane. The surface 130bof the sealing part 130 and the terminal surface 150b of the signal conductor 150 are located on approximately the same plane or the same plane. The terminal surface 140b and the terminal surface 150b may be provided with unevenness in a part thereof. Even in such a case, when at least a part of the terminal surface 140b and the terminal surface 150b is on the same plane as the surface 130a or the surface 130b of the sealing part and does not protrude from the surface 130a or the surface 130b, the terminal surface 140b and the terminal surface 150b may be regarded as existing on the same plane as the surface 130a or the surface 130b.

In this specification, when the difference in height in the y-axis direction between the surface 130a of the sealing part 130 and the terminal surface 140b of the current conductor 140 is within 50 μm, the surface 130a of the sealing part 130 and the terminal surface 140b of the current conductor 140 may be regarded as being located on approximately the same plane. The difference in height is preferably within 20 μm.

In this specification, when the difference in height in the y-axis direction between the surface 130b of the sealing part 130 and the terminal surface 150b of the current conductor 150 is within 50 μm, the surface 130a of the sealing part 130 and the terminal surface 140b of the current conductor 140 may be regarded as being located on approximately the same plane. The difference in height is preferably within 20 μm.

By making the terminal parts of the current conductor 140 and the signal conductor 150 into terminal surfaces that are on the same plane as the outer surface of the sealing part 130, miniaturization is easier compared to a current sensor including terminals protruding from the sealing part 130.

Since the terminal surface 140a and the terminal surface 140b of the current conductor 140 do not protrude in the planar direction from the sealing part 130, the distance between the terminal surfaces and the magnetoelectric conversion element 20 becomes closer, and heat generation of the current conductor 140 due to the measured current can be suppressed.

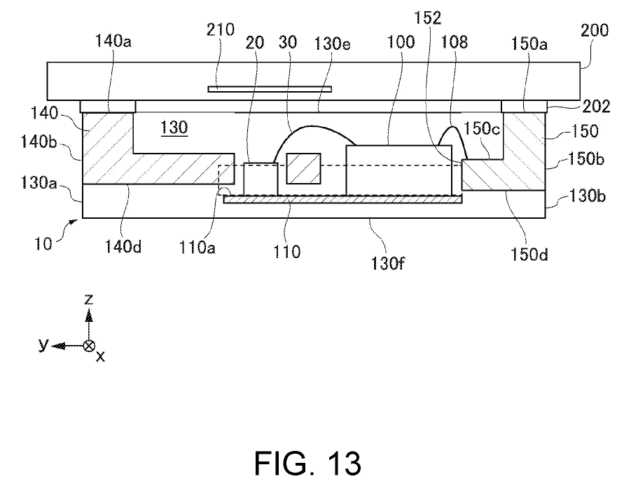

The circuit surface of the signal processing IC 100 and the magnetic sensing surface of the magnetoelectric conversion element 20 are surrounded in two directions by the terminal parts 140 and 150. Therefore, electromagnetic fields from the outside are blocked by the terminals, and a shielding effect is exhibited. Furthermore, the magnetic sensing surface of the magnetoelectric conversion element 20 faces the direction of the terminal surface 140a and the terminal surface 150a. Therefore, when mounted on a substrate via solder, by arranging a metal plate at a position on the substrate facing the magnetic sensing surface, electromagnetic fields from the surface may also be blocked. An example is shown in FIG. 13. In FIG. 13, the current sensor 10 has the terminal surface 140a and the terminal surface 150a electrically connected to a substrate 200 via a solder 202. The substrate 200 incorporates a metal plate 210 at a position at least overlapping with the magnetoelectric conversion element 20 in the thickness direction (z-axis direction). The metal plate 210 may be composed of a conductive material having copper as a main component. By arranging the metal plate 210 in an inner layer of the substrate 200, a surface distance can be ensured. The metal plate 210 may be wiring installed on the substrate 200.

Plating containing tin may be applied to the terminal surface 140a of the current conductor 140 and the terminal surface 150a of the signal conductor 150. Plating containing tin may be applied to the terminal surface 140a and the terminal surface 140b of the current conductor 140, as well as the terminal surface 150a and the terminal surface 150b of the signal conductor 150.

Among the members sealed in the sealing part 130, the members exposed from the surface of the sealing part 130 are only the terminal surface 140a and the terminal surface 140b of the current conductor 140, as well as the terminal surface 150a and the terminal surface 150b of the signal conductor 150. The sealing part 130 seals the support part 110, and the support part 110 is not exposed from the sealing part 130.

Moreover, when the minimum distance along the surface 130e of the sealing part 130 between the terminal surface 140a of the current conductor 140 and the terminal surface 150a of the signal conductor 150 is defined as a surface distance L1, the surface distance L1 is 79% or more of a length L2 of the sealing part 130 in the direction along the surface distance. For example, a length L3 of the terminal surface 140a in the y-axis direction and a length L4 of the terminal surface 150a in the y-axis direction may be 0.4 mm or less, and the surface distance L1 may be 3 mm or more. Thereby, the surface distance can be ensured in a small space. The surface distance L1 may be 8 mm or less.

More preferably, when the minimum distance along the surface 130e of the sealing part 130 between the terminal surface 140a of the current conductor 140 and the terminal surface 150a of the signal conductor 150 is defined as a surface distance L1, the surface distance L1 is 85% or more of the length L2 of the sealing part 130 in the direction along the surface distance. For example, the length L3 of the terminal surface 140a in the y-axis direction and the length L4 of the terminal surface 150a in the y-axis direction may be 0.3 mm or less, and the surface distance L1 may be 3.4 mm or more. Thereby, the surface distance can be ensured in a small space. The surface distance L1 may be 8 mm or less.

The surface distance L1 is preferably the shortest distance between the terminal surface 140a and the terminal surface 150a. Here, among the surface 130e, the surface 130f, a surface 130c sharing sides with both the surface 130e and the surface 130f, and a surface 130d, in the case where a conductor is exposed at a location sandwiched between the terminal surface 140a and the terminal surface 150a in top view, the surface distance becomes smaller. For example, in the case where a tie bar exists on the surface 130c or the surface 130d, the surface distance becomes smaller by a width corresponding to the tie bar. Therefore, no conductor is exposed between the terminal surface 140a and the terminal surface 150a. That is, among the surface 130e, the surface 130f, the surface 130c sharing sides with both the surface 130e and the surface 130f, and the surface 130d, only an insulator exists at a location sandwiched between the terminal surface 140a and the terminal surface 150a in top view. Since the current sensor 10 is a SON type package, even without the presence of a tie bar, it may be fixed to a dicing tape during singulation. Therefore, scattering of the current sensor 10 can be suppressed.

The thickness h1 of the portion where the thickness of the current conductor 140 is thinner than other portions, that is, the portion 1401 sealed within the sealing part 130, is thicker than the thickness h2 of a portion 1501 where the thickness of the signal conductor 150 is thinner than other portions, that is, the portion sealed within the sealing part 130. Thereby, the resistance value of the current conductor 140 is reduced, and heat generation caused by current flowing through the current conductor 140 can be suppressed.

The thickness of the portion 1501 of the signal conductor 150 may be half or less of the thickness h3 of the lead frame constituting the current conductor 140 and the signal conductor 150. Thereby, the portion 1501 of the signal conductor 150 can be easily realized by etching processing. The thickness h2 of the portion 1501 of the signal conductor 150 may be made thinner than the thickness h4 of the signal processing IC 100. Thereby, a step in the z-axis direction may be provided between the portion of the signal processing IC 100 to which the wire 108 is connected and the portion of the signal conductor 150 to which the wire 108 is connected. This facilitates the connection between the wire 108 and the signal conductor 150.

Furthermore, it is preferable that silver plating is applied to the portion of the signal conductor 150 bonded to the wire 108. Thereby, fluctuation in sensitivity due to magnetism in the plating can be suppressed.

The sealing part 130 includes an inorganic filler. The sealing part 130 is manufactured in a single mold sealing process as shown in the manufacturing method of the current sensor 10 described later, and the entire sealing part 130 is integrally configured. As a result, the sealing part 130 has substantially no interface that does not cross the filler. Here, "there is substantially no interface that does not cross the filler" means that there is no interface that does not cross the filler extending over 95% or more, or 99% or more of the width direction or height direction of the sealing part 130 inside the sealing part 130 as shown in FIG. 1. That is, in the sealing part 130, even in the case where such an interface exists inside the sealing part 130 at a ratio of less than 1%, or less than 5% of the width direction or height direction of the sealing part 130, it may be said that "there is substantially no interface that does not cross the filler".

According to Patent Document 1, an interface within the sealing part is formed between the sealing part formed by the first sealing and the sealing part formed by the second sealing. The interface within the sealing part is a plane that the filler included in the sealing part may touch but does not cross. The interface within the sealing part is approximately parallel to the width direction or height direction of the sealing part 130. Moreover, since the filler only contacts and does not cross the plane including this interface, the ratio of the area of the filler at the sealing part interface to the sealing part is very small relative to the filler filling rate of the sealing resin. For example, the ratio of the area of the filler to the area of the sealing resin in this plane is 5% or less of the filler filling rate when surface grinding or the like is not performed after the first sealing. In the case where grinding is performed for removing foreign matter or modifying the surface after the first sealing, the filler tends to be exposed at the interface. Even in that case, since the filler significantly slows down the grinding rate, it is reasonable that the grinding is less than the radius of the filler. Therefore, the ratio of the area of the filler at the sealing part interface to the sealing part is 50% or less of the filler filling rate.

The current sensor 10 is manufactured by singulation as in the manufacturing method described later. Therefore, cross sections of the filler exist on the surfaces of the sealing part 130 (the surface 130a, the surface 130b, the surface 130c, and the surface 130d which are side surfaces) that become cut surfaces when singulated.

Since there is no interface inside the sealing part 130, the surface 130c and the surface 130d, which are cut surfaces, have no interface that does not substantially cross the filler. Therefore, the cross sections of the filler on the surface 130c and the surface 130d are exposed by an amount equivalent to the filling rate of the filler in the sealing part 130. In the sealing part 130, the ratio of the area of the cross sections of the filler exposed from the surfaces of the surface 130c and the surface 130d to the area of the surface 130c and the surface 130d is within a range that cannot be said to have a significant difference relative to the filling rate of the internal filler. The range that cannot be said to have a significant difference is, for example, a range in which no significant difference is recognized when the significance level is 0.05. Alternatively, the ratio of the area of the cross sections of the filler exposed from the surfaces of the surface 130c and the surface 130d to the area of the surface 130c and the surface 130d matches within a range of 5% relative to the filling rate of the internal filler. Since there is no interface of the mold resin within the sealing part 130, peeling or cracks along the interface do not occur.

The surface 130e and the surface 130f of the sealing part 130 are not cut surfaces in the case of singulation, so there is no interface crossing the filler, that is, no cross section of the filler. However, in the case of surface processing the surface 130e or surface 130f of the sealing part 130 by blasting or the like, an interface crossing the filler may exist on the surface 130e or a surface 130f of the sealing part 130. In that case as well, similar to the sealing part interface, the ratio of the area of the filler at the sealing part interface to the sealing part is 50% or less of the filler filling rate.

In the interface within the sealing part or the surface 130e and the surface 130f described so far, since the ratio of the filler changes, there is a local change in Young's modulus or linear expansion coefficient, and local stress tends to be applied to the surroundings thereof. On the other hand, since in Patent Document 1, there is an interface within the sealing part, local stress may cause problems in characteristics or reliability. Moreover, in the form described in Patent Document 2, since a part of the side surfaces of the sealing part is also formed by filling in addition to the front surface and the back surface, similar problems tend to occur. On the other hand, in the current sensor 10, the only surfaces where the area of the filler relative to the area of the sealing part is 50% or less of the filling rate of the filler relative to the mold resin are the surface 130e and the surface 130f. Therefore, in the current sensor 10, characteristic variations due to spatial variations in local stress, or reliability problems such as cracks are unlikely to occur.

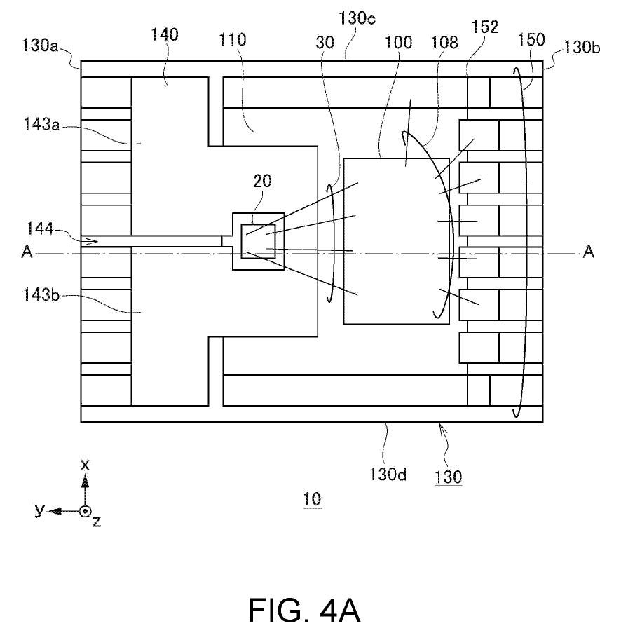

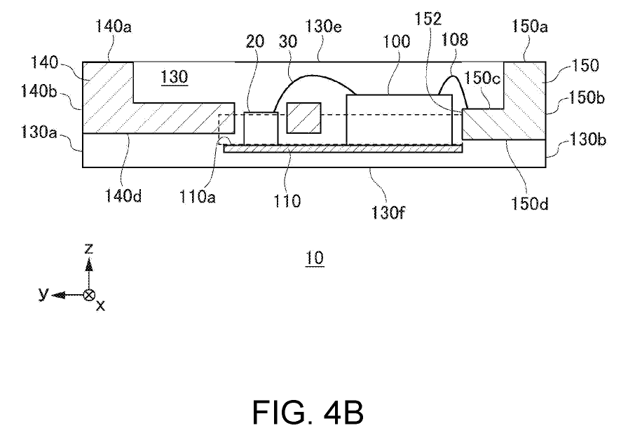

FIG. 4A and FIG. 4B show the internal configuration of the current sensor 10 according to a second embodiment. FIG. 4A is a schematic plan view of the current sensor 10 according to the second embodiment as viewed from the mounting surface side (z-axis direction). FIG. 4B is a cross-sectional view of the current sensor 10 shown in FIG. 4A taken along line A-A.

The current sensor 10 according to the second embodiment differs from the current sensor 10 according to the first embodiment in that the current conductor 140 does not have the step part 142, and the signal conductor 150 has a step part 152.

The surface 140d opposite to the terminal surface 140a of the current conductor 140 on the same side as the surface 130e of the sealing part 130 is not located on the same plane as the surface 110a of the support part 110. The signal conductor 150 is provided with the step part 152 so as to be separated from the current conductor 140. The height from the surface 130f opposite to the surface 130e, which is the mounting surface of the sealing part 130, to the surface 140d of the current conductor 140 is higher than the height from the surface 130f of the sealing part 130 to the surface 110a of the support part 110, so that the surface 140d of the current conductor 140 does not contact the surface 110a of the support part 110.

Since the current conductor 140 does not have the step part 142, heat generation associated with an increase in the resistance value of the current conductor 140 can be suppressed.

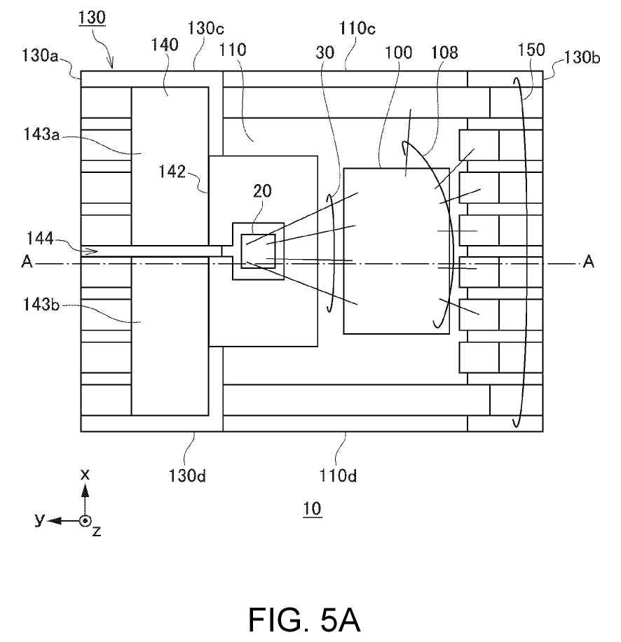

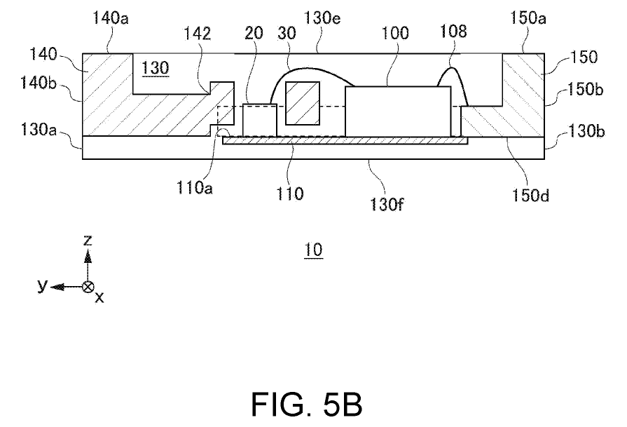

FIG. 5A and FIG. 5B show the internal configuration of the current sensor 10 according to a third embodiment. FIG. 5A is a schematic plan view of the current sensor 10 according to the third embodiment as viewed from the mounting surface side (z-axis direction). FIG. 5B is a cross-sectional view of the current sensor 10 shown in FIG. 5A taken along line A-A.

The current sensor 10 according to the third embodiment differs from the current sensor 10 according to the first embodiment in that the width of the support part 110 in the x-axis direction is longer than the width of the support part 110 in the x-axis direction of the current sensor 10 according to the first embodiment, and an end surface 110c and an end surface 110d of the support part 110 are exposed from the surface 130c and the surface 130d, which are side surfaces of the sealing part 130.

In the first embodiment, when sealing is performed, the sealing resin may apply stress to the support part 110, and the signal conductor 150 may be deformed. By the support part 110 extending beyond the signal conductor 150 to the side surface of the sealing part 130 in plan view, not only the signal conductor 150 but also the entire lead frame may support the support part 110, and deformation of the signal conductor 150 can be suppressed. In this case, by using a support part 110 having a comparative tracking index equal to or higher than that of the sealing part 130, creeping discharge along the support part 110 can be suppressed. Specifically, it is desirable to use polyimide or epoxy.

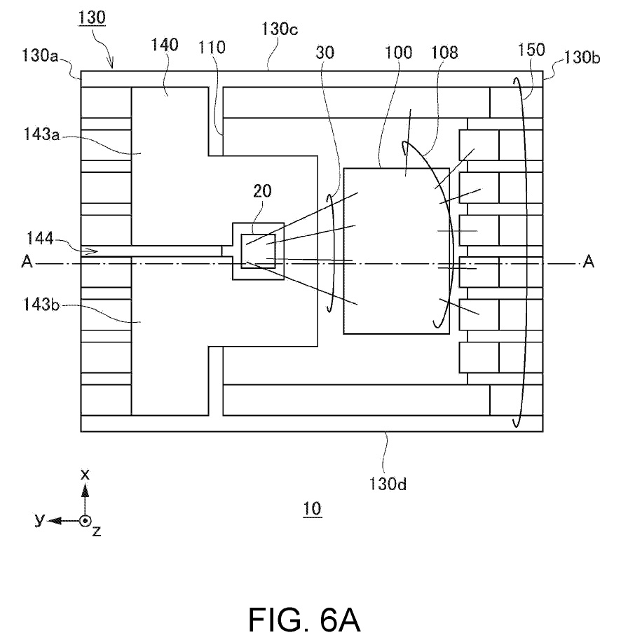

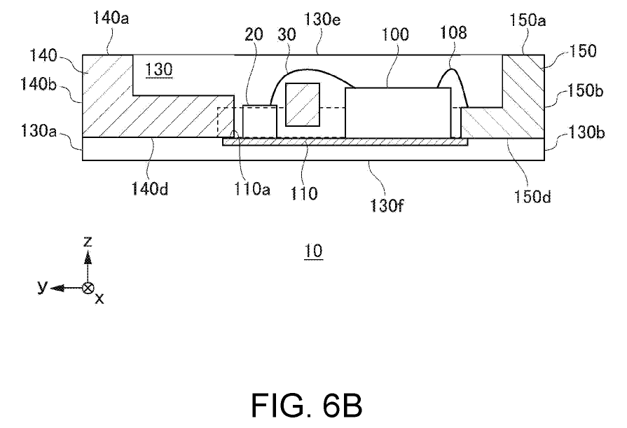

FIG. 6A and FIG. 6B show the internal configuration of the current sensor 10 according to a fourth embodiment. FIG. 6A is a schematic plan view of the current sensor 10 according to the fourth embodiment as viewed from the mounting surface side (z-axis direction). FIG. 6B is a cross-sectional view of the current sensor 10 shown in FIG. 6A taken along line A-A.

The current sensor 10 according to the fourth embodiment differs from the current sensor 10 according to the first embodiment in that the current conductor 140 and the signal conductor 150 do not have the step part 142 and the step part 152, and the surface 140d of the current conductor 140 is in contact with the surface 110a of the support part 110. By adopting such a configuration, the current conductor 140 and the signal conductor 150 may be formed only by etching one surface of the lead frame, and manufacturing efficiency can be improved.

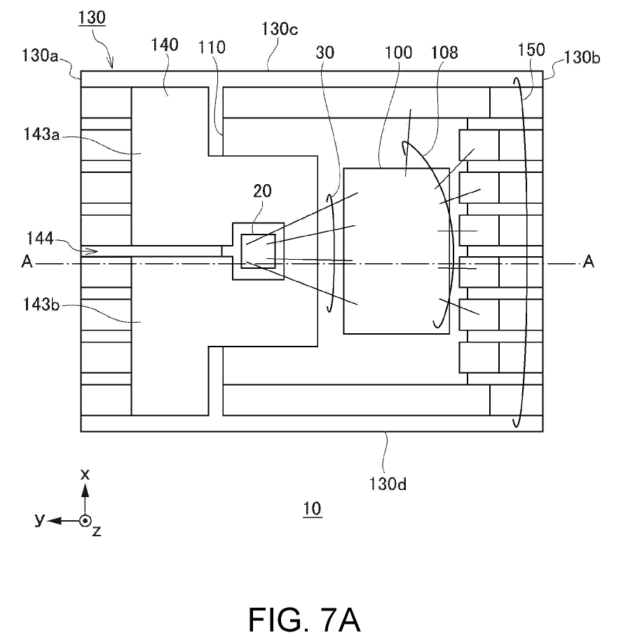

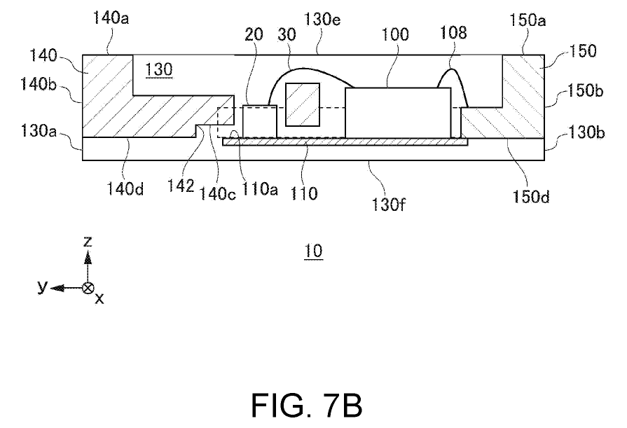

FIG. 7A and FIG. 7B show the internal configuration of the current sensor 10 according to a fifth embodiment. FIG. 7A is a schematic plan view of the current sensor 10 according to the fifth embodiment as viewed from the mounting surface side (z-axis direction). FIG. 7B is a cross-sectional view of the current sensor 10 shown in FIG. 7A taken along line A-A.

The current sensor 10 according to the fifth embodiment differs from the current sensor 10 according to the first embodiment in that the step part 142 of the current conductor 140 is formed only on the surface 140c facing the surface 110a of the support part 110. After creating the shape of the current conductor 140 and the signal conductor 150 other than the step part 142 by etching one surface of the lead frame, the step part 142 may be formed on the surface 140c of the current conductor 140 by coining processing.

Alternatively, the current conductor 140 and the signal conductor 150 including the step part 142 may be formed by etching both surfaces of the lead frame. By forming the current conductor 140 and the signal conductor 150 by etching including the step part 142, the current conductor 140 and the signal conductor 150 can be manufactured efficiently.

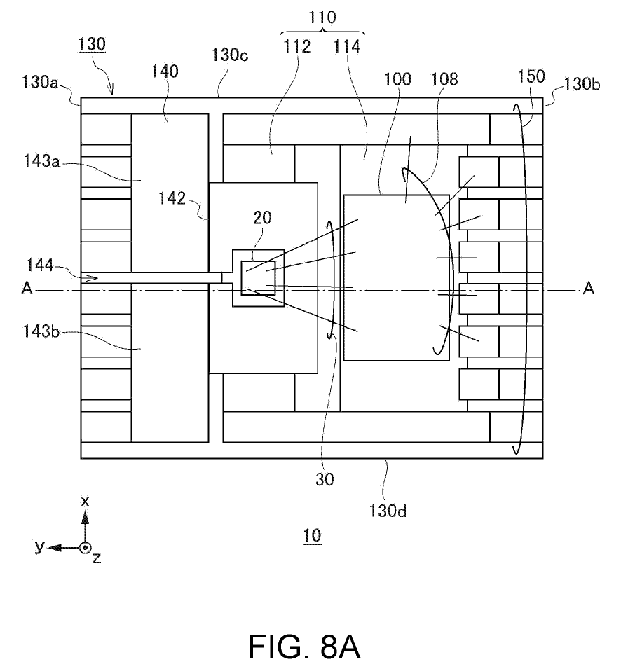

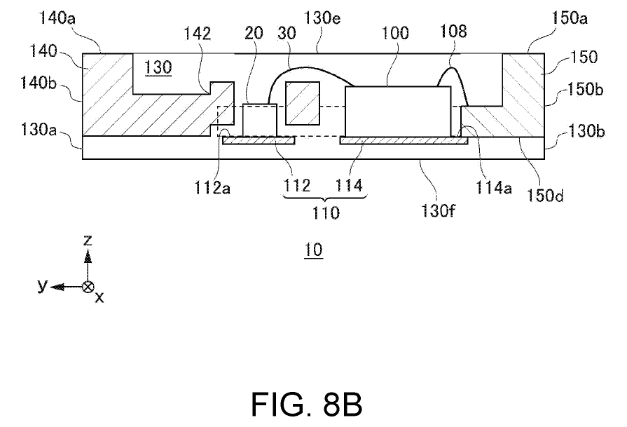

FIG. 8A and FIG. 8B show the internal configuration of the current sensor 10 according to a sixth embodiment. FIG. 8A is a schematic plan view of the current sensor 10 according to the sixth embodiment as viewed from the mounting surface side (z-axis direction). FIG. 8B is a cross-sectional view of the current sensor 10 shown in FIG. 8A taken along line A-A.

The current sensor 10 according to the sixth embodiment differs from the current sensor 10 according to the first embodiment in that the support part 110 is divided into a support part 112 that supports the magnetoelectric conversion element 20 and a support part 114 that supports the signal processing IC 100.

When there are many regions where gaps between members sealed by the sealing part 130 are narrow, the fluidity of the mold resin deteriorates in the mold sealing process, making it difficult to fill the entire lead frame constituting the current conductor 140 and the signal conductor 150 with the mold resin. By dividing the support part 110 into two, a gap is created between the support part 112 and the support part 114, and the mold resin may pass through the gap to improve the embedding property of the mold resin. This can improve the withstand voltage performance of the sealing part 130.

In the second embodiment, the fourth embodiment, and the fifth embodiment, examples have been described in which the support part 110 is not exposed from the surface 130c and the surface 130d of the sealing part 130. However, the support part 110 according to the second embodiment, the fourth embodiment, and the fifth embodiment may be exposed from the surface 130c and the surface 130d of the sealing part 130, similarly to the current sensor 10 according to the third embodiment. Similarly, in the current sensor 10 according to the sixth embodiment, the support part 112 and the support part 114 may be exposed from the surface 130cand the surface 130d of the sealing part 130, similarly to the current sensor 10 according to the third embodiment.

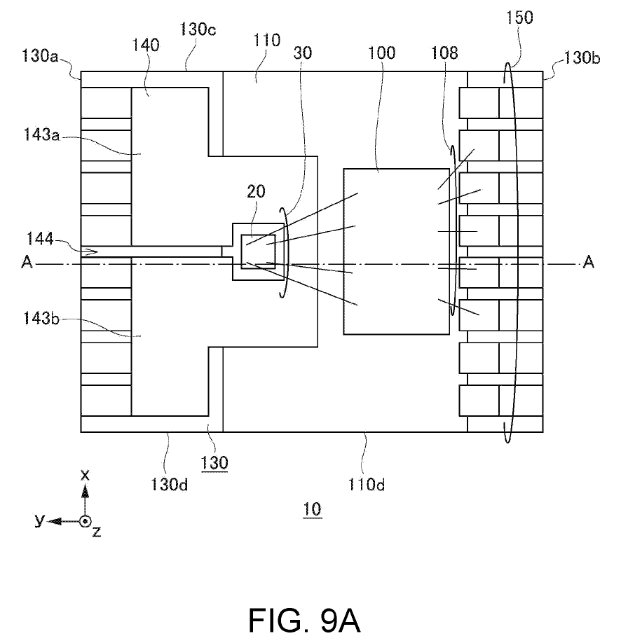

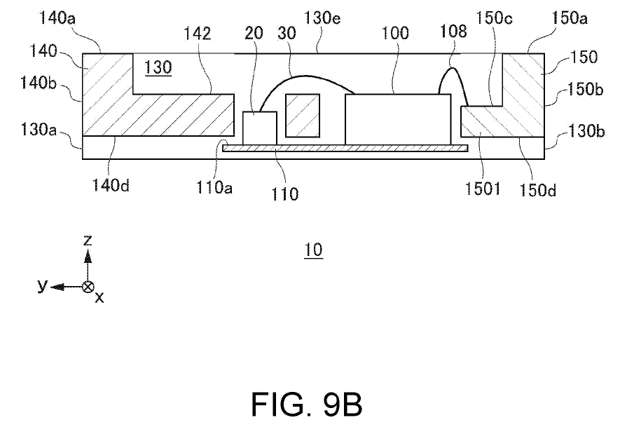

FIG. 9A and FIG. 9B show the internal configuration of the current sensor 10 according to a seventh embodiment. FIG. 9A is a schematic plan view of the current sensor 10 according to the seventh embodiment as viewed from the mounting surface side (z-axis direction). FIG. 9B shows a cross-sectional view of the current sensor 10 shown in FIG. 8A taken along line A-A.

The current sensor 10 according to the seventh embodiment differs from the current sensor 10 according to the first embodiment in that the support part 110 is not in contact with the lead frame constituting the current conductor 140 and the signal conductor 150, and in that the width of the support part 110 in the x-axis direction is longer than the width of the support part 110 of the current sensor 10 according to the first embodiment in the x-axis direction, and the end surface 110c and the end surface 110d of the support part 110 are exposed from the surface 130c and the surface 130d, which are side surfaces of the sealing part 130.

By separating the support part 110 from the lead frame constituting the current conductor 140 and the signal conductor 150, discharge from the signal processing IC 100 to the signal conductor 150 along the interface between the support part 110 and the sealing part 130 does not occur.

The interface between the support part 110 and the signal conductor 150 is often more prone to peeling than the mold resin due to differences in water absorption rate or linear expansion coefficient. The absence of the interface between the support part 110 and the signal conductor 150 provides a reliability advantage of suppressing peeling. Here, the support part 110 and the signal conductor 150 may also be separated in top view. As a result, even when the support part 110 is pushed up by the sealing part 130, contact with the signal conductor 150 may be avoided.

The seventh embodiment is realized by fixing the support part 110 to a portion of the lead frame constituting the current conductor 140 and the signal conductor 150 that does not remain as the current sensor 10, and providing a step. Similarly to the third embodiment, since the support part 110 may be adhered collectively rather than being adhered individually to the current sensor 10, manufacturing efficiency is good. Specifically, the material of the support part 110 wound in a reel form may be pulled out and adhered, and there is no need to cut it for each current sensor 10 and then bond it with a specially prepared mold.

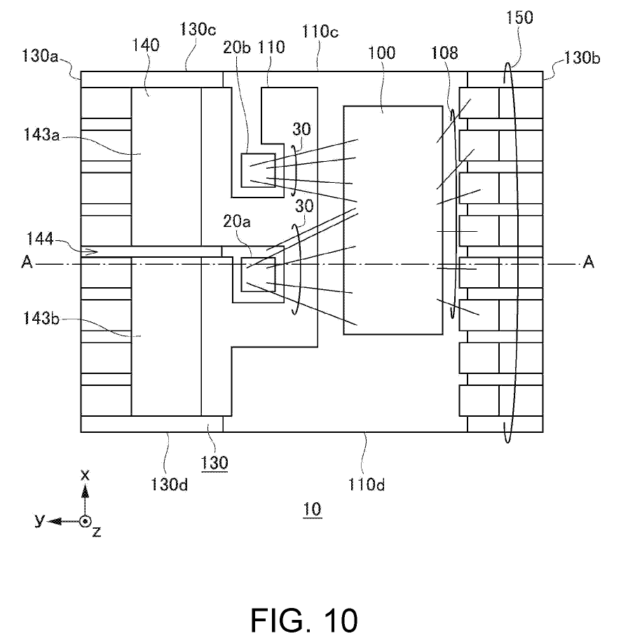

FIG. 10 is a schematic diagram showing a case where two magnetoelectric conversion elements 20a and 20b are arranged in the seventh embodiment. The magnetoelectric conversion element 20a is arranged in the slit 144, and the magnetoelectric conversion element 20b is arranged at a position across the current conductor 140 from the magnetoelectric conversion element 20a. As a result, in the case where the difference between them is amplified by the signal processing IC, the influence of uniform noise from the outside may be canceled. At this time, it is desirable to partially surround the magnetoelectric conversion element 20b with the current conductor 140 so that the coupling capacitance between the wire 30 connected to the magnetoelectric conversion element 20a and the current conductor 140 is equal to the coupling capacitance between the wire 30 connected to the magnetoelectric conversion element 20b and the current conductor 140. In the case where the projected area of the current conductor 140 from the z-axis direction is large in this way, it is desirable to support the support part 110 with the lead frame existing outside the current sensor 10. Thereby, there is no need to provide a bonding portion between the support part 110 and the signal conductor 150 inside the current sensor 10, and the current sensor 10 may be made more compact.

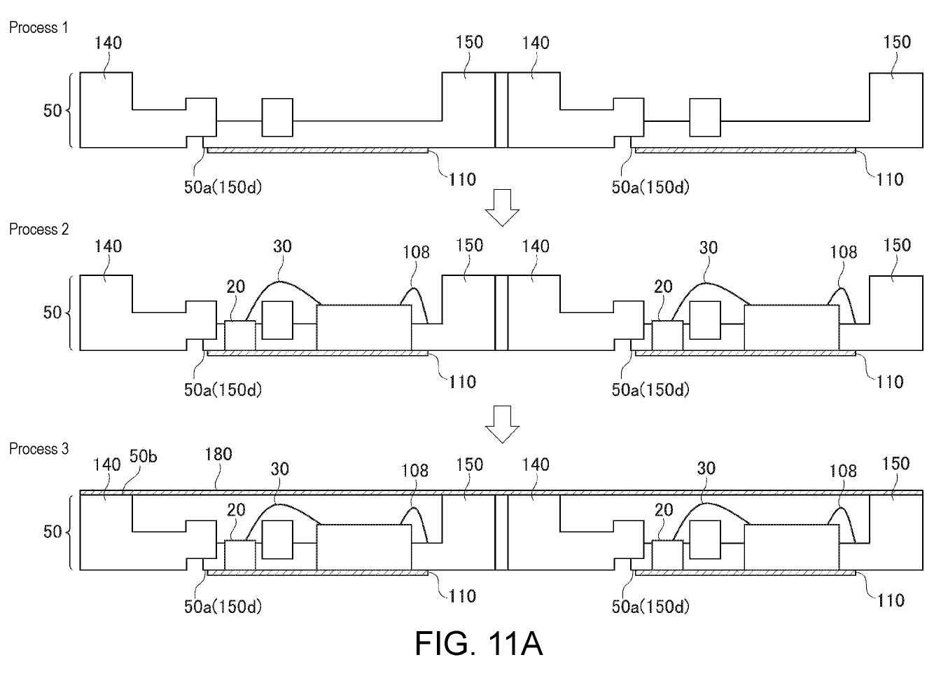

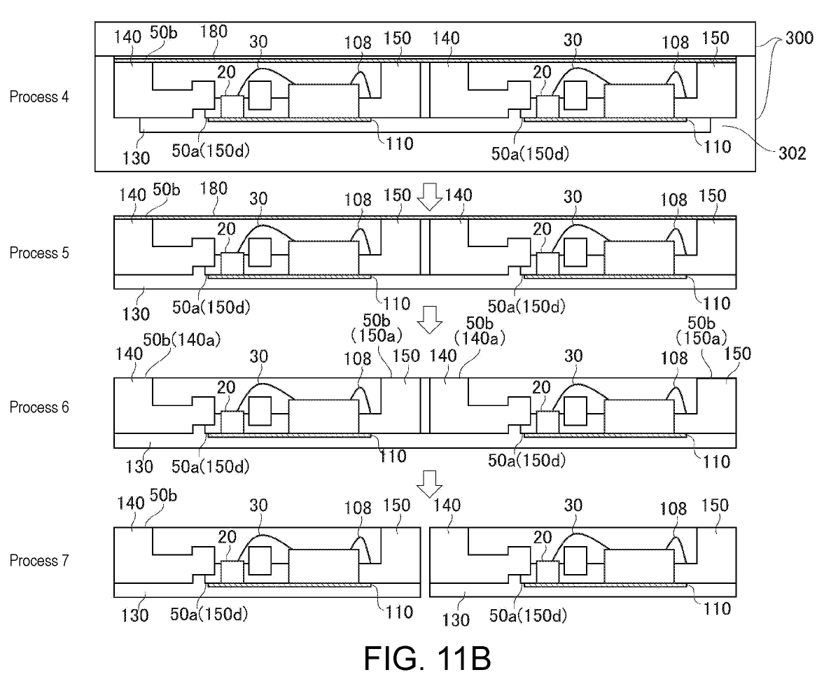

Next, a manufacturing method of the current sensor 10 according to the first embodiment will be described with reference to FIG. 11A and FIG. 11B.

In Process 1, a lead frame 50 in which a plurality of sets of the current conductor 140 and the signal conductor 150 are formed is prepared, wherein the one surface 110a of the support part 110 is adhered to a portion corresponding to the signal conductor 150 on one surface 50a of the lead frame 50. The lead frame 50 may be prepared by forming the current conductor 140 and the signal conductor 150 by etching, and then bonding the one surface 110a of the support part 110 such as polyimide tape to a portion corresponding to the signal conductor 150 on the one surface 50a of the lead frame 50. After etching the lead frame 50, the step part 142 of the current conductor 140 may be formed by half-cut processing or coining processing. After etching the lead frame 50, silver plating may be applied to the surface of the signal conductor 150 that has become thinner due to etching, that is, the surface to which the wire 108 is connected in Process 2.

In Process 2, the magnetoelectric conversion element 20 is arranged on the surface 110a of the support part 110 such that, in plan view, it is at least partially surrounded by the current conductor 140 within the slit 144 formed in the current conductor 140, with the magnetic sensing surface facing opposite the support part 110, and the signal processing IC 100 is arranged on the surface 110a of the support part 110 at a position different from the position where the magnetoelectric conversion element 20 is arranged, with the circuit surface facing opposite the support part 110. The position different from the position where the magnetoelectric conversion element 20 is arranged on the surface 110a of the support part 110 is, for example, a position opposing the magnetoelectric conversion element 20 across the U-shaped folded portion of the current conductor 140 in plan view. Furthermore, the magnetic sensing surface of the magnetoelectric conversion element 20 and the circuit surface of the signal processing IC 100 are electrically connected by the wire 30, and the signal processing IC and the signal conductor 150 are electrically connected by the wire 108.

In Process 3, a film 180 is pasted on a surface 50b opposite to the surface 50a of the lead frame 50. The film 180 may be, for example, polyimide tape. The film 180 contacts only the non-etched surface of the lead frame 50, that is, the surface having the greatest distance from the surface 50a in a direction perpendicular to the surface 50a. The film 180 prevents the mold resin from adhering to the terminal surface.

In Process 4, the lead frame 50 with the film 180 pasted thereon is arranged within the cavity of a mold 300. Furthermore, the cavity is filled with mold resin, and the magnetoelectric conversion element 20, the signal processing IC 100, the support part 110, the wire 30, and the wire 108 are sealed with the mold resin to form the sealing part 130. At this time, the cavity is flat over the entire portion of the lead frame to be assembled as the current sensor 10, and the entire surface of the film 180 contacts the mold. The region where the cavity is flat is flat in a region spanning a plurality of current sensors 10, and does not need to be flat over the entire lead frame. By doing so, there is no need to recreate the mold even if the size of the current sensor 10 is changed. Here, the end part of the lead frame 50 is held by sandwiching both surfaces with the mold 300. On the other hand, for the portion of the current sensor 10, the surface of the mold 300 is spaced apart from the support part 110 so that the support part 110, the current conductor 140, the signal conductor 150, the magnetoelectric conversion element 20, and the signal processing IC 100 are not exposed from the sealing part 130 opposite to the terminal surface. This is achieved by providing a step 302 larger than the thickness of the support part 110 in one of the upper mold and the lower mold of the mold 300. That is, the support part 110 is spaced apart from the surface of the mold 300. The region where the mold 300 holds the lead frame 50 by sandwiching it from both surfaces may be any region that does not form the current sensor 10, and does not necessarily need to be only the end part of the lead frame 50. For example, the region between the terminal constituting the current sensor 10 and a terminal constituting an adjacent current sensor 10 may be pressed by the mold 300. In that case, it is possible to suppress the resin from flowing between the film 180 and the mold 300 due to the entire lead frame 50 bending significantly.

Here, due to the step 302 of the mold 300, the mold 300 and the terminal parts of the support part 110 and the current conductor 140 or the signal conductor 150 have a structure that does not sandwich the terminal surface and the surface opposing the terminal surface from above and below. Therefore, during sealing, no pressure from the mold 300 for molding is applied to the terminal surface, and without the film 180, the mold resin would flow around and cover the terminal surface. Since the film 180 is pasted on the terminal surface 140a and the terminal surface 150a of the lead frame 50, the mold resin is prevented from covering the terminal surface 140a and the terminal surface 150a even in a situation where no pressure is applied, and the current sensor 10 in which the terminals are exposed from the sealing part 130 while the internal structure is not exposed may be manufactured with a single sealing.

In Process 5, after the mold resin has solidified, it is removed from the mold 300 with the film 180 still pasted thereon.

In Process 6, the film 180 is removed from the surface 50b of the lead frame 50 sealed with the mold resin. The terminal surface 140a of the current conductor 140 and the terminal surface 150a of the signal conductor 150 that are exposed by removing the film 180 may be processed by blasting to completely remove the film components. Furthermore, plating containing tin may be applied to the terminal surface 140aof the current conductor 140 and the terminal surface 150a of the signal conductor 150.

In Process 7, the lead frame 50 sealed with the mold resin is singulated by cutting to manufacture a plurality of current sensors 10.

Through the above Processes, the entire sealing part 130 of the current sensor 10 may be integrally formed with only a single mold sealing process. Accordingly, when mold sealing is performed using mold resin containing filler, there is substantially no interface that does not cross the filler in the sealing part 130. Moreover, although cross-sections of the filler exist on the surfaces of the sealing part 130 that become cut surfaces when singulated (the surface 130a, the surface 130b, the surface 130c, and the surface 130d which are side surfaces), there is no interface inside the sealing part 130. Therefore, there is substantially no interface that does not cross the filler on the surface 130c and the surface 130d which are cut surfaces. Accordingly, the cross-sections of the filler on the surface 130c and the surface 130d are exposed by an amount equivalent to the filling rate of the filler in the sealing part 130. The cross-sections of the filler in the portion where there is no terminal surface 140b on the surface 130a of the sealing part 130 and in the portion where there is no terminal surface 150b on the surface 130b of the sealing part 130 are also exposed by an amount equal to or greater than the filling rate of the filler in the sealing part 130. Since there is no interface of the mold resin within the sealing part 130, peeling or cracks along the interface do not occur.

As described above, according to the manufacturing method of the current sensor 10 shown in FIG. 11A and FIG. 11B, the current sensor 10 may be manufactured that ensures surface distance, prevents cracks and the like from occurring within the sealing part 130, ensures withstand voltage, and enables miniaturization.

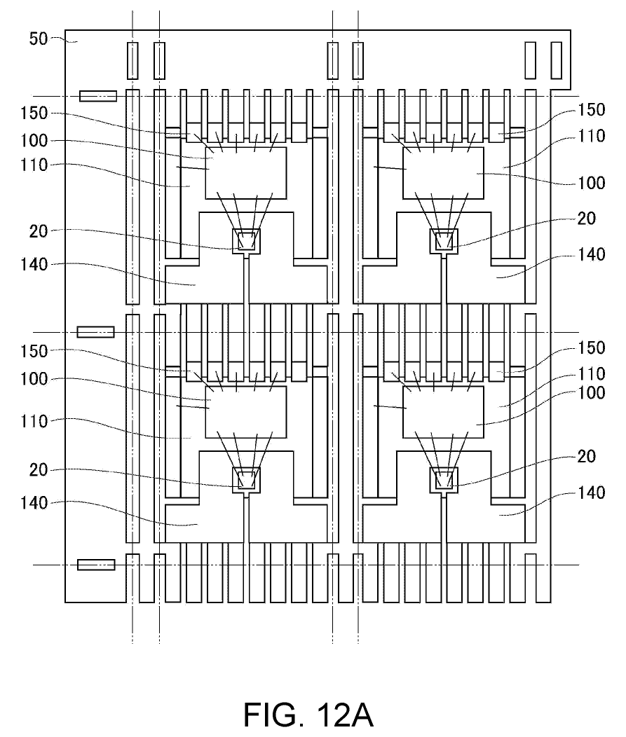

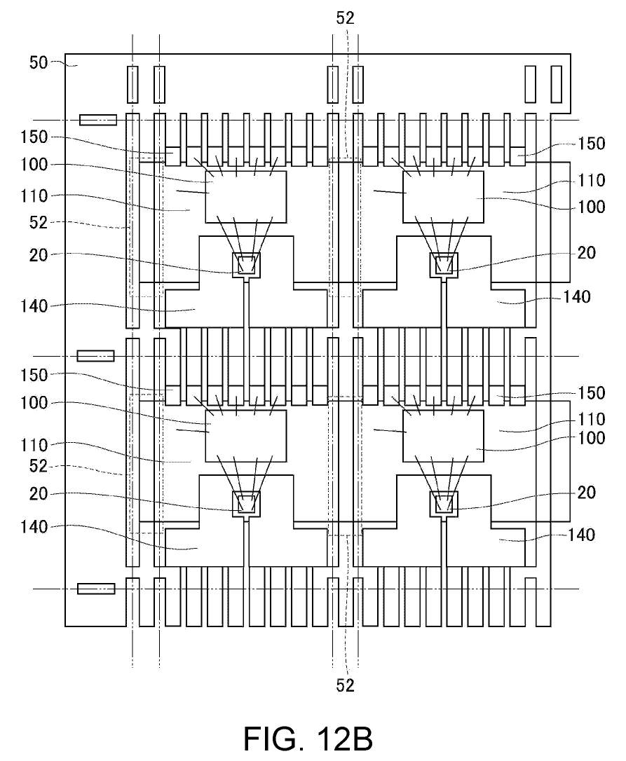

Here, FIG. 12A shows a plan view of the state after completing Process 2 for realizing the first embodiment. The support part 110 is individually pasted to the lead frame 50 for each element of the current sensor 10. In this state, after sealing, the current sensor 10 may be manufactured by cutting a chain line part. When realizing the second, fourth, fifth, and sixth embodiments, the support part 110 may also be individually pasted to the lead frame 50 in the same manner as in FIG. 12A.

Here, FIG. 12B shows a plan view of the state after completing Process 2 for realizing the seventh embodiment. This differs from the plan view for realizing the first embodiment in that the support part 110 is arranged spanning a plurality of current sensors 10. Moreover, by providing a step part or spacer on the lead frame 50 at a dotted line part 52 and then pasting the support part 110, the support part 110 and the current conductor 140, and the support part 110 and the signal conductor 150 may be separated. When realizing the third embodiment, the support part 110 may also be arranged spanning a plurality of current sensors 10.

As described above, the disclosure has been described using the embodiments, but the technical scope of the disclosure is not limited to the scope described in the above embodiments. It is apparent to those skilled in the art that various modifications or improvements may be added to the above embodiments. It is apparent from the description of the claims that forms with such modifications or improvements added may also be included in the technical scope of the disclosure.

It should be noted that the execution order of each processing such as operations, procedures, steps, and stages in the devices, systems, programs, and methods shown in the claims, specification, and drawings may be realized in any order, unless specifically indicated as "before" or "prior to," and unless the output of a previous processing is used in a subsequent processing. Even if the operation flow in the claims, specification, and drawings is described using "first," "next," and the like for convenience, this does not mean that implementation in this order is required.

What is claimed is:

1. A current sensor, comprising:
at least one magnetoelectric conversion element;
a current conductor that at least partially surrounds the at least one magnetoelectric conversion element in plan view and through which a measurement current measured by the at least one magnetoelectric conversion element flows;
a signal processing IC that processes a signal output from the at least one magnetoelectric conversion element;
a support part that supports, with a first surface, at least one of a surface opposite to a magnetic sensing surface of the at least one magnetoelectric conversion element and a surface opposite to a circuit surface of the signal processing IC;
a signal conductor that is connected to the circuit surface of the signal processing IC via electrical conductor and transmits a signal output from the signal processing IC; and
a sealing part integrally configured that seals the at least one magnetoelectric conversion element, a part of the current conductor, the electrical conductor, the signal processing IC, a part of the signal conductor, and at least a part of the support part,
wherein in a case where a surface of the support part opposite to the first surface is defined as a second surface, at least two surfaces among the first surface, the second surface, and a side surface of the support part are in contact with the sealing part without being exposed from the sealing part,
the current conductor has a first terminal surface exposed from a first surface of the sealing part facing the first surface of the support part, and a second terminal surface exposed from a second surface continuous from the first surface of the sealing part,
the signal conductor has a third terminal surface exposed from the first surface of the sealing part, and a fourth terminal surface exposed from a third surface opposite to the second surface of the sealing part,
the second surface of the sealing part and the second terminal surface are located on a same plane, and
the third surface of the sealing part and the fourth terminal surface are located on a same plane.

2. The current sensor according to claim 1,
wherein the first surface of the sealing part, the first terminal surface, and the third terminal surface are located on a same plane.

3. The current sensor according to claim 2,
wherein the sealing part comprises an inorganic filler.

4. The current sensor according to claim 3,
wherein the sealing part has no interface within the sealing part that does not cross the filler.

5. The current sensor according to claim 1,
wherein the signal conductor is in contact with the first surface of the support part.

6. The current sensor according to claim 3,
wherein a cross section of the filler exists on a surface of the sealing part.

7. The current sensor according to claim 3,
wherein the sealing part has a fourth surface opposite to the first surface, a fifth surface, and a sixth surface opposite to the fifth surface, and
an interface within the sealing part that does not cross the filler is not exposed on the fifth surface and the sixth surface.

8. The current sensor according to claim 3,
wherein the sealing part has a fourth surface opposite to the first surface, a fifth surface, and a sixth surface opposite to the fifth surface, and
a cross section of the filler on the fifth surface and the sixth surface of the sealing part are exposed at a same ratio within a range of 5% as a filling rate of the filler in the sealing part.

9. The current sensor according to claim 1,
wherein in a case where a minimum distance along the first surface of the sealing part between the first terminal surface and the third terminal surface is defined as a surface distance, the surface distance is 79% or more of a length of the sealing part in a direction along the surface distance.

10. The current sensor according to claim 1,
wherein in a case where a minimum distance along the first surface of the sealing part between the first terminal surface and the third terminal surface is defined as a surface distance, the surface distance is 85% or more of a length of the sealing part in a direction along the surface distance.

11. The current sensor according to claim 1,
wherein in a case where a minimum distance along the first surface of the sealing part between the first terminal surface and the third terminal surface is defined as a surface distance, the surface distance is 8 mm or less.

12. The current sensor according to claim 1,
wherein among members sealed in the sealing part, members exposed from a surface of the sealing part are only the first terminal surface and the second terminal surface of the current conductor, and the third terminal surface and the fourth terminal surface of the signal conductor.

13. The current sensor according to claim 1,
wherein at least a part of a second surface opposite to a first surface of the current conductor on a same side as the first surface of the sealing part, and the first surface of the support part are located on a same plane.

14. The current sensor according to claim 1,
wherein the current conductor has a step part such that a second surface opposite to a first surface facing the first surface of the sealing part is separated from the first surface of the support part.

15. The current sensor according to claim 1,
wherein the sealing part seals the support part, and the support part is not exposed from the sealing part.

16. The current sensor according to claim 1,
wherein the sealing part seals a part of the support part, the support part is insulating, and an end part of the support part is exposed from the sealing part.

17. The current sensor according to claim 16,
wherein the sealing part has a fourth surface opposite to the first surface, a fifth surface, and a sixth surface opposite to the fifth surface, and
an exposed surface of the end part exposed from the sealing part is located on a same plane as the fifth surface or the sixth surface of the sealing part.

18. The current sensor according to claim 16,
wherein the support part is separated from both the current conductor and the signal conductor, and a part of the sealing part exists between the current conductor and the signal conductor.

19. The current sensor according to claim 1,
wherein the magnetoelectric conversion element and the signal processing IC are connected by a wire, and a roundness having a radius of 20% or more of a plate thickness of the current conductor exists at a position in the current conductor facing the wire.

20. The current sensor according to claim 1,
wherein the sealing part has a fourth surface opposite to the first surface, and
a plane in which a ratio of an area of a filler to an area of the sealing part is half or less of an average filling rate of the filler in mold resin constituting the sealing part exists only on the first surface and the fourth surface, among planes existing inside or on a surface of the sealing part.

21. The current sensor according to claim 1,
wherein the magnetic sensing surface of the magnetoelectric conversion element and the circuit surface of the signal processing IC are arranged toward the first terminal surface and the second terminal surface side, and a distance between the magnetic sensing surface and the first surface of the sealing part is smaller than a thickness of a lead frame.

22. The current sensor according to claim 21, further comprising:
a substrate on which the current sensor is mounted via solder, wherein a metal plate is arranged in the substrate at a position facing the magnetoelectric conversion element.

23. The current sensor according to claim 1,
wherein the sealing part has a fourth surface opposite to the first surface, a fifth surface of the sealing part sharing sides with both the first surface and the fourth surface, and a sixth surface opposite to the fifth surface, and
among the first surface, the fourth surface, the fifth surface, and the sixth surface of the sealing part, only an insulator exists at a location sandwiched between the first terminal surface and the third terminal surface in top view.

24. The current sensor according to claim 1,
wherein the current conductor has a step in a direction away from the support part in side view, the support part exists only between the step and the third terminal surface in plan view, and an end surface of the support part overlaps with an end part of the signal conductor.

25. The current sensor according to claim 18,
wherein the support part is separated from the signal conductor in top view.

26. A manufacturing method of current sensor, the method comprising:
preparing a lead frame in which a plurality of sets of a current conductor through which a measurement current measured by at least one magnetoelectric conversion element flows and a signal conductor that transmits a signal output from a signal processing IC that processes a signal output from the at least one magnetoelectric conversion element are formed, wherein a first surface of a support part is partially adhered to a second surface of the lead frame;
arranging the at least one magnetoelectric conversion element on the first surface of the support part so as to be at least partially surrounded by the current conductor in plan view, and arranging the signal processing IC at a position different from a position where the at least one magnetoelectric conversion element is arranged on the first surface of the support part;
electrically connecting the at least one magnetoelectric conversion element and the signal processing IC by electrical conductor, and electrically connecting the signal processing IC and the signal conductor by electrical conductor;
pasting a film on a first surface opposite to the second surface of the lead frame;
arranging the lead frame in a cavity of a mold with a gap formed between the cavity and the support part;
filling mold resin into the cavity and sealing the at least one magnetoelectric conversion element, the signal processing IC, the support part, and the electrical conductor with the mold resin;
removing the film from the first surface of the lead frame sealed with the mold resin; and
singulating the lead frame sealed with the mold resin by cutting.

27. The manufacturing method of current sensor according to claim 26,
wherein the cavity of the mold is flat over regions of a plurality of current sensors.

28. The manufacturing method of current sensor according to claim 26,
wherein the lead frame is formed by etching.

29. The manufacturing method of current sensor according to claim 26, the method comprising:
removing organic matter from a surface where the lead frame is exposed, after the removing the film.
